(19) United States
(12) Patent Application Publication
(10) Pub. No.: US 2006/0169981 A1
(43) Pub. Date: Aug. 3, 2006

(54) Thin film transistor array panel for organic electro luminescent display

(76) Inventor: In-Su Joo, Seongnam-city (KR)

Correspondence Address: CANTOR COLBURN, LLP, 55 GRIFFIN ROAD SOUTH, BLOOMFIELD, CT, 06002, US

(21) Appl. No.: 11/344,795

(22) Filed: Jan. 31, 2006

(30) Foreign Application Priority Data
Jan. 31, 2005 (KR) 10-2005-0008558

(51) Int. Cl. H01L 29/76

(52) U.S. Cl. 257/66

(57) ABSTRACT

The light emitting efficiency of an organic electro luminance substance depends on the selected electro luminescent (EL) material. Each color of organic EL substances has a different light emitting efficiency from another color. The current source of a pixel having an EL layer with good light emitting efficiency is shared with another pixel having an EL layer that is less efficient. Therefore the current source is used efficiently, and the aperture ratio of an organic light emitting display and the quality of the display is improved.

This application claims priority to Korean Patent Application No. 2005-008558, filed on Jan. 31, 2005, and all the benefits accruing therefrom under 35 U.S.C. §119, and the contents of which in its entirety are herein incorporated by reference.

### BACKGROUND OF THE INVENTION

1. Field of the Invention

The present invention relates to an organic light emitting display (“OLED”).

2. Discussion of the Background

An OLED displays images by electrically exciting organic materials. The OLED comprises an anode electrode that supplies holes, a cathode electrode that supplies electrons and an organic light emitting substance (e.g., electro luminescent material) layer confined between the cathode electrode and the anode electrode. If a voltage is applied between the cathode electrode and the anode electrode, and current is supplied to the electro luminescent (“EL”) material, then light is emitted from the EL layer. The color of the light depends on the EL material. Some organic light emitting substances emit red light, some emit green light and some emit blue light. The light emitting efficiency depends on the EL material, wherein the light emitting efficiency is defined by light intensity emitted from unit EL material with respect to unit electric current.

### BRIEF SUMMARY OF THE INVENTION

The present invention provides an array substrate that connects a portion of a pixel thin film transistor (‘TFT’) to another pixel TFT to provide additional electric current to a less efficient organic electro luminance (“EL”) layer.

Exemplary embodiments of the present invention disclose a thin film transistor array panel, comprising: a first switching transistor; a first driving transistor coupled to the first switching transistor; a second switching transistor; a second driving transistor coupled to the second switching transistor; and a third driving transistor coupled to the second driving transistor. The thin film transistor array panel further comprises: a first organic electro luminescent matter layer; a second organic electro luminescent matter layer; a first pixel including the first organic electro luminescent matter layer; and a second pixel including the second organic electro luminescent matter layer; wherein each pixel includes a current source line. The source electrode of the third driving transistor is coupled to the current source line of the first pixel, the drain electrode of the third driving transistor is coupled to the drain electrode of the second driving transistor, and the gate electrode of the third driving TFT is coupled to the gate electrode of the second driving TFT.

Additional features of the present invention will be set forth in the description which follows, and in part will be apparent from the description, or may be learned by practice of the invention. It is also to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the present invention and are incorporated in and constitute a part of this specification, illustrate exemplary embodiments of the present invention and together with the detailed description serve to explain the principles of the present invention.

FIG. 1 shows a plan view layout of an exemplary embodiment of a thin film transistor (“TFT”) array panel for an OLED according to the present invention.

FIG. 2 shows a schematic diagram of the TFT array panel shown in FIG. 1.

FIG. 3 shows a cross-sectional view of III-III′ of FIG. 1.

FIG. 4 shows a cross-sectional view of IV-IV′ of FIG. 1.

FIGS. 5, 8, 11 and 14 show plan view layouts in steps for forming the TFT array panel of FIGS. 1, 3 and 4.

FIGS. 6 and 7 show cross-sectional views of VI-VI′ and VII-VII′, respectively, of FIG. 5.

FIGS. 9 and 10 show cross-sectional views of IX-IX′ and X-X′, respectively, of FIG. 8.

FIGS. 12 and 13 show cross-sectional views of XII-XII′ and XIII-XIII′, respectively, of FIG. 11.

FIGS. 15 and 16 show cross-sectional views of XV-XV′ and XVI-XVI′, respectively, of FIG. 14.

FIG. 17 shows a schematic diagram of another exemplary embodiment of the present invention.

FIG. 18 shows a schematic diagram of another exemplary embodiment of the present invention.

FIG. 19 shows a schematic diagram of another exemplary embodiment of the present invention.

### DETAILED DESCRIPTION OF THE INVENTION

Hereinafter, exemplary embodiments of the present invention will be described in detail with reference to the attached drawings such that the present invention can be easily put into practice by those skilled in the art. However, the present invention is not limited to the exemplary embodiments, but may be embodied in various forms.

In the drawings, thicknesses are enlarged for the purpose of clearly illustrating layers and areas. If it is mentioned that a layer, a film, an area, or a plate is placed on a different element, it includes a case that the layer, film, area, or plate is placed right on the different element, as well as a case that another element is disposed therebetween. On the contrary, if it is mentioned that one element is placed right on another element, it means that no element is disposed therebetween.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

OLEDs according to exemplary embodiments of the present invention will now be described in detail with reference to the accompanying drawings in which like elements are denoted by like reference numerals throughout the whole specification.

The luminescent efficiency of organic EL materials depends on the color of the material. The luminance efficiency of commonly used green (G) organic EL materials is better than that of commonly used red (R) organic EL materials. The luminance efficiency of commonly used red organic EL materials is better than that of blue (B) organic EL materials.

Even though the efficiency of a blue EL material is worse than that of a green EL material, sufficient luminance is obtained by supplying enough electric current to the blue EL material. Exemplary embodiments of the present invention include a structure that supplies more current to a blue EL material layer and less electric current to a green EL material layer.

Electric current is supplied through a driving TFT when the channel of the driving TFT is open. A data signal is applied through the switching TFT when the channel of the switching TFT is open. The efficiency of the EL layer is measured by the brightness emitted from the EL layer when a unit current is supplied to the EL layer.

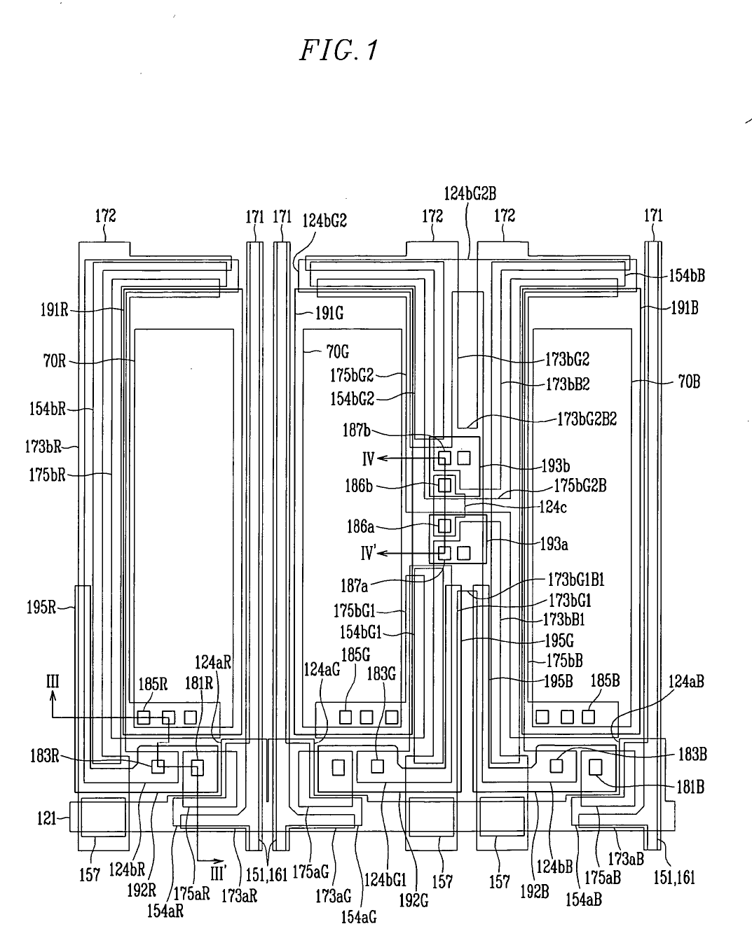

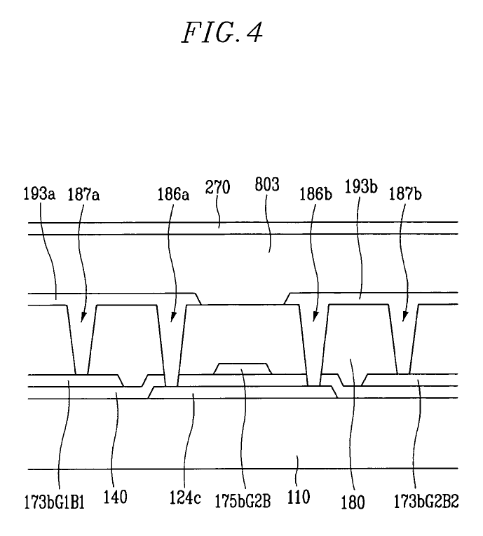

Red pixels are formed as described herein below with reference to FIGS. 1-4.

A gate line 121 is formed on an insulation plate 110 and extends transversally. A first gate electrode 124aR is formed on the gate line 121. A second gate electrode 124bR is formed on a same layer as the gate line 121.

The gate line 121 and the second gate electrode 124bR may comprise two metal layers that have different physical characteristics. One metal layer may has a low electric resistivity, such as Al, Al alloy, or other similar metals, and the other metal layer may have a good adhesive characteristic with indium tin oxide (ITO) or indium zinc oxide (IZO), such as Cr, Mo, MoW or other similar metals. The side surfaces defining the gate line 121 are oblique and form an angle ranging from about 30 degrees to about 80 degrees with a major surface defining the insulation plate 110.

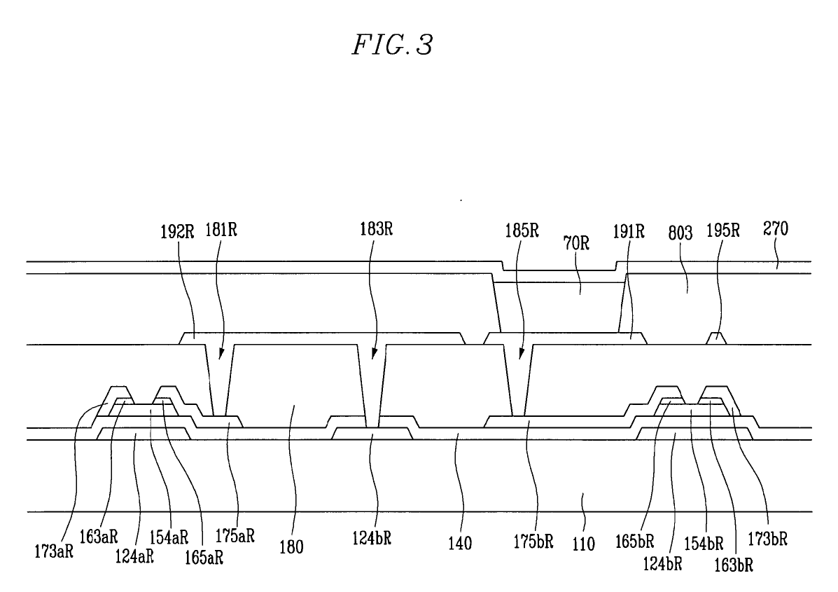

A gate insulation layer 140 is formed on the gate line 121. The gate insulation layer 140 may be made of SiNₓ. A hydrogenated amorphous silicon (a-Si) line 151 and an a-Si island 154bR are formed on the gate insulation layer 140. The a-Si line 151 extends transversally to the gate line 121. A portion of the a-Si line 151 protrudes toward the first gate electrode 124a, and forms a first channel area. The first channel area overlaps the first gate electrode 124a. The a-Si island 154bR overlaps the second gate electrode 124bR, as illustrated in FIG. 3.

Ohmic contact layer patterns 161 [Note: Not shown in Figs.], 165aR, 163bR, 165bR are formed on the a-Si patterns. The ohmic contact layer patterns are made of silicide or n⁺ a-Si. A protrusion 163aR comes from the ohmic contact layer line 161 [Note: Not shown in Figs.]. As best seen with reference to FIG. 3, the protrusion 163aR and an ohmic contact layer island 165aR are formed on the a-Si protrusion 154aR. The ohmic contact layer islands 163bR and 165bR are formed on the a-Si island.

As illustrated in FIG. 1, a-Si layer 157 is formed over the gate line 121 that is crossed over by a current source line 172. An ohmic contact layer is formed on the a-Si layer 157. The side surfaces defining the a-Si layers 151, 154bR, 157 and the ohmic contact layers 161, 165aR, 163bR, 165bR are tapered. The taper angle defined by the tapered sides is in a range from about 30 degrees to about 80 degrees.

A data line 171, a first drain electrode 175aR, a current source line 172 and a second drain electrode 175bR are formed on the gate insulation layer 140, the a-Si pattern 151 and 154bR, and the ohmic contact layer patterns 161 [Note: Not shown in Figs.], 165aR, 163bR, and 165bR.

The data line 171 and the current source line 172 extend longitudinally and both cross the gate line 121, as illustrated in FIG. 1. A first source electrode 173aR extends from the data line 171 toward a first drain electrode 175aR. A second source electrode 173bR extends from the current source line 172 toward a second drain electrode 175bR.

A first gate electrode 124aR, the first source electrode 173aR and the first drain electrode 175aR form a switching TFT along with the protrusion 154aR of the semiconductor line 151. A second gate electrode 124bR, the second source electrode 173bR and the second drain electrode 175bR form a driving TFT along with the semiconductor island 154bR. The data line 171, the first drain electrode 175aR, the second drain electrode 175bR and the current source line 172 may be made of Mo or Mo alloy.

The data line 171, the first drain electrode 175aR, the second drain electrode 175bR and the current source line 172 may be formed of multi layers, such as with a metal comprising Al or Al alloy. When Al or Al alloy is used in forming double metal layers, the Al or Al alloy may be formed under Mo or Mo alloy. When Al or Al alloy is used in forming three metal layers, the Al or Al alloy may be formed between the other two layers. The side surfaces defining the data line 171, the first drain electrode 175aR, the second drain electrode 175bR and current source line 172 may taper, and the taper angle defined by the tapered sides is in a range from about 30 degrees to about 80 degrees. A semiconductor layer 157 along with an ohmic contact layer is formed in the area that the current source line 172 overlaps the gate line 121 to prevent damage on the current source line 172 and the gate line 121.

As seen with reference to FIG. 3, a passivation layer 180 is formed on the TFT channel, the data line 171, the drain electrodes 175aR and 175bR and the current source line 172. The passivation layer 180 may be made of a-Si:C:O or a-Si:O:F that can be formed with plasma enhanced chemical vapor deposition (“PECVD”). The passivation layer 180 may be made of a photo resistive organic matter. A silicon nitride layer or a silicon oxide layer may be formed on the TFT channel area if the passivation layer 180 is made of an organic material.

Contact holes 181R, 183R, and 185R may be formed in the passivation layer 180 exposing a portion of the first drain electrode 175aR, a portion of the second gate electrode 124bR and a portion of the second drain electrode 175bR, respectively. A pixel electrode 191R and a connection assistant 192R are formed on the passivation layer 180. The pixel electrode 191R is coupled to the second drain electrode 175bR through the contact hole 185R. The contact assistant 192R couples the first drain electrode 175aR and the second gate electrode 124bR through the contact holes 181R and 183R. The contact assistant 192R comprises a connecting portion coupling the first drain electrode 175aR to the second gate electrode 124bR, a vertical portion 195R and a horizontal portion connecting the vertical portion 195R to the connection portion. The horizontal portion and the vertical portion 195R of the connecting assistant 192R form a storage capacitance along with the second source electrode 173bR.

The pixel electrode 191R and the connection assistant 192R may be made of a transparent conductor, such as IZO, ITO, or other similar materials. The pixel electrode 191R and the connection assistant 192R may be made of a low resistivity conductor, such as Al, Al alloy or other similar materials.

A wall 803 may be formed on the passivation layer 180. The wall 803 may be made of an organic or an inorganic insulation material. The wall 803 is formed along the edge of the pixel electrode 191R. A light emitting layer 70R [Note: designated “70”, not “70R” in FIG. 3]is formed on the pixel electrode 191R. The wall 803 confines the light emitting layer 70R, as illustrated in FIG. 3. The light emitting layer 70 emits red light, green light, or blue light. The light emitting layer 70 may be made of an organic material.

A common electrode 270 is formed on the light emitting layer 70R and the wall 803. The common electrode 270 may be made of a low resistivity metal such as Al, for example. The common electrode 270 may also be made of ITO or IZO. An assistant electrode may be formed between the wall 803 and the common electrode 270. The assistant electrode may reduce resistance of the common electrode 270.

It will be recognized by those skilled in the pertinent art that the structure of a red pixel is described above. The structures of a green pixel and a blue pixel differ little from the structure of the red pixel. The second gate electrode and the second source electrode of the green pixel are each divided into two parts. One part of the second gate electrode of the green pixel is coupled to the gate electrode of the blue pixel. One part of the second source electrode of the green pixel is coupled to the second source electrode of the blue pixel.

With reference again to FIG. 1, the second gate electrode of the green pixel is divided into an upper second gate electrode 124bG2 and a lower second gate electrode 124bG1. The semiconductor layer of the second TFT is divided into an upper semiconductor layer 154bG2 and a lower semiconductor layer 154bG1.

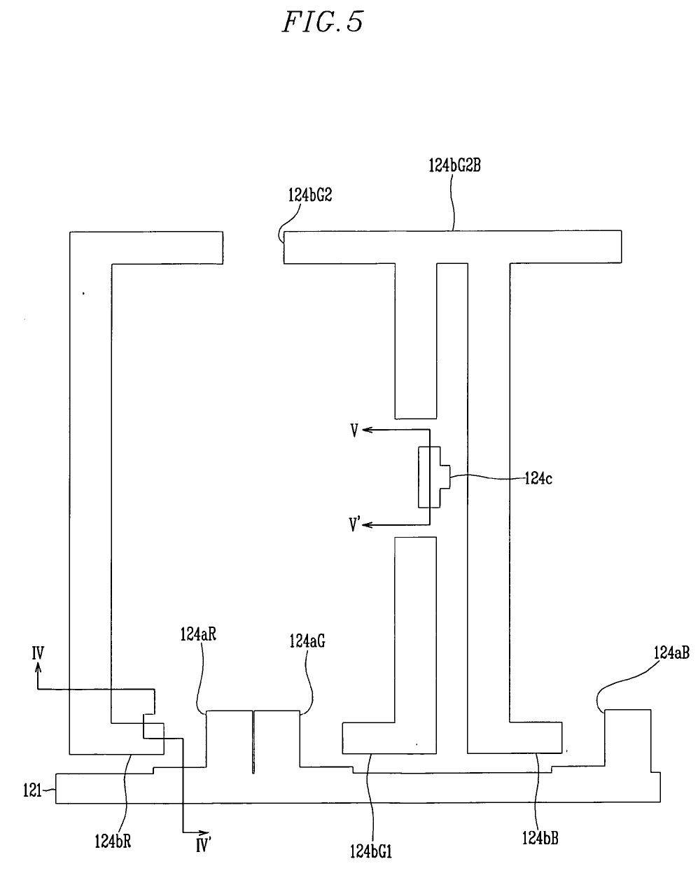

The second gate electrode 124bB of the blue pixel is formed as one. The semiconductor pattern 154bB is also formed as one. The upper gate electrode 124bG2 of the green pixel is coupled to the second gate electrode 124bB through a gate electrode connector 124bG2B (FIG. 5).

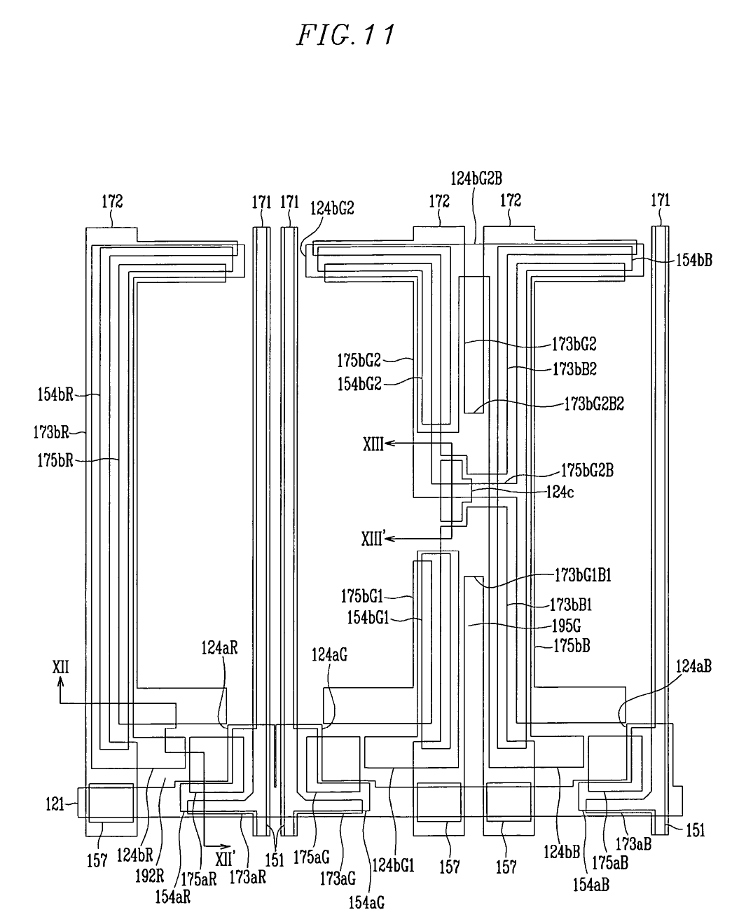

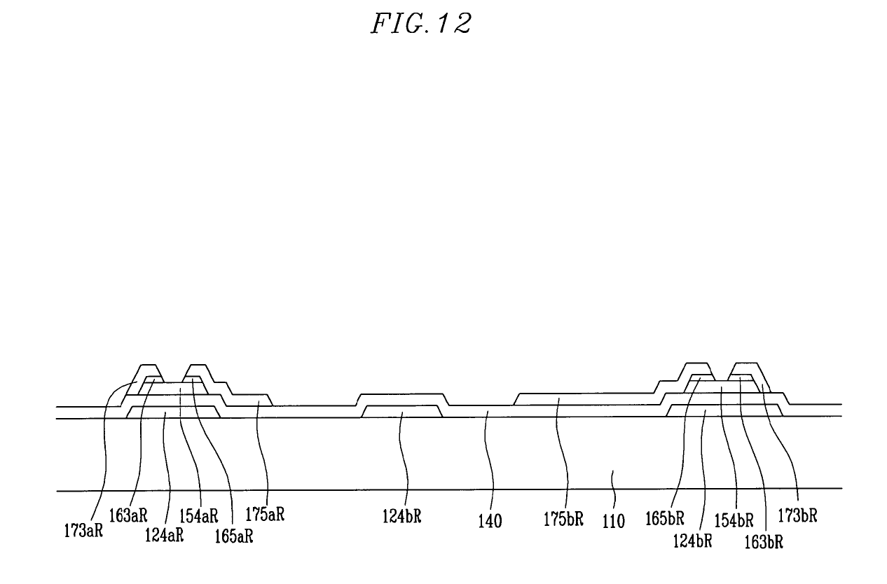

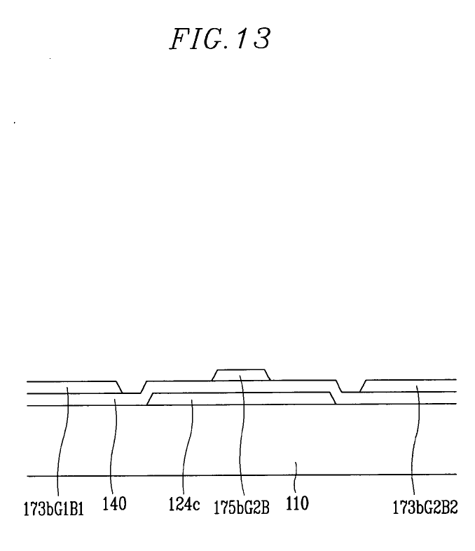

Because the layout of the green pixel is similar to a mirror image of the layout of the red pixel, and the layout of the blue pixel is similar to the layout of the red pixel, the current source line 172 of the green pixel lies adjacent to the current source line 172 of the blue pixel. The current source line 172 of the green pixel is coupled to the lower second source electrode 173bG1 [Note: Not shown in FIG. 1 or 11] and to the upper second source electrode 173bG2. The current source line 172 of the blue pixel is coupled to the lower second source electrode 173bB1 and to the upper second source electrode 173bB2. The lower second source electrode 173bG1 [Note: Not shown in FIG. 1 or 11] of the green pixel is coupled to the lower second source electrode 173bB1 of the blue pixel through the connector 173bG1B1. The upper second source electrode 173bG2 of the green pixel is coupled to the upper second source electrode 173bB2 of the blue pixel through the connector 173bG2B2.

The second drain electrode of the green pixel is divided into an upper second drain electrode 175bG2 and a lower second drain electrode 175bG1. The upper second drain electrode 175bG2 of the green pixel is coupled to the second drain electrode 175bB through a connector 175bG2B. The lower second source electrodes 173bG1 and 173bB1 are coupled to the current source line 172 through a first current source connector 124c and second current source connectors 193a and 193b. Contact holes 186a, 186b, 187a and 187b are formed in the passivation layer 180. The contact holes 186a, 186b, 187a and 187b expose both end portions of the current source line 124b, the connector of the first source electrode connector 173bG1B1 and the second source electrode connector 173bG2B2, respectively. The second connectors 193a and 193b are formed on the passivation layer 180, and couple the first connector 124c to the first source electrode connector 173bG1B1 and the second source electrode connector 173bG2B2 through the contact holes 186a, 186b, 187a and 187b. The second current source connectors 193a and 193b may be made of ITO, IZO, or a low resistivity metal such as Al, for example.

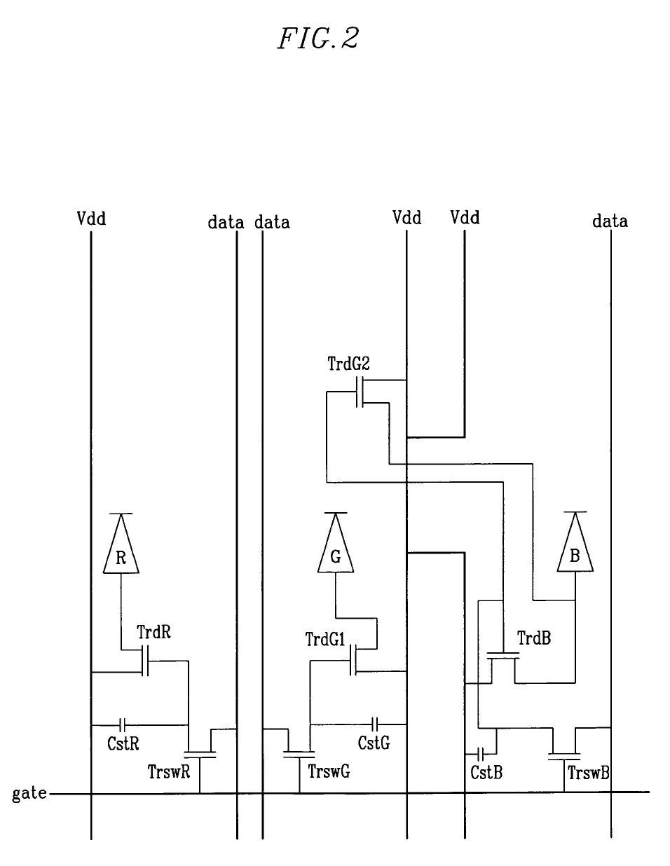

FIG. 2. shows a circuit diagram of the exemplary embodiment described above. A switching transistor TrswR and a driving transistor TrdR are formed in a red pixel. A switching transistor TrswG and two driving transistors TrdG1 and TrdG2 are formed in the green pixel. The gate electrode and the drain electrode of the driving transistor TrdG2 are coupled to the gate electrode and the drain electrode of the driving transistor TrdB of a blue pixel, respectively. The source electrode of the driving transistor TrdG2 and the source electrode of the driving transistor TrdB are coupled to a current source line Vdd. The current source line Vdd is applied with a predetermined voltage. Current applied to the EL layer is supplied through the current source line Vdd.

The OLED displays a better image by supplying more current to the least efficient blue color and less current to the most efficient green color. The structure may be modified to supply more current to a less than efficient EL material, the efficiency depending on efficiency of colors.

A method for manufacturing the above described embodiment is described hereinafter.

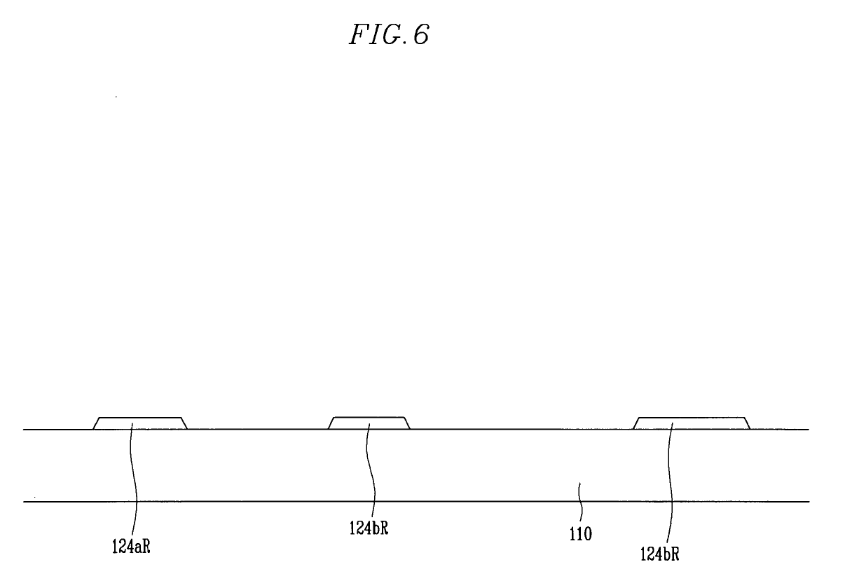

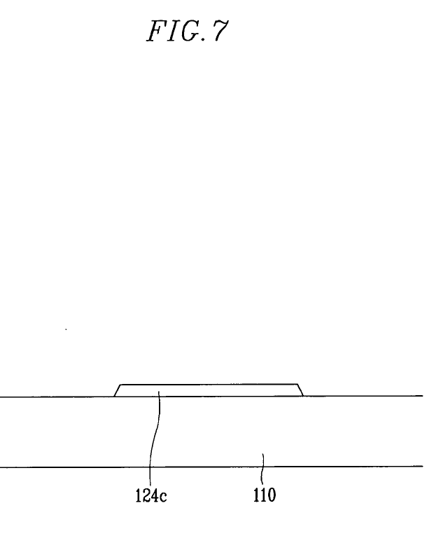

As shown in FIGS. 5, 6 and 7, a metal layer is formed on a transparent insulator 110 such as glass, for example. A gate line 121, a first gate electrode 124a, a second gate electrode 124b and a first current source line connector 124c are formed with the metal layer by photolithography. A second gate electrode of a green pixel is divided into a lower second gate electrode 124bG1 and an upper second gate electrode 124bG2. A first current source line connector 124c is formed between the lower second gate electrode 124bG1 and the upper second gate electrode 124bG2. The upper second gate electrode 124bG2 of the green pixel is connected to the second gate electrode 124bB of the blue pixel through the connector 124bG2B.

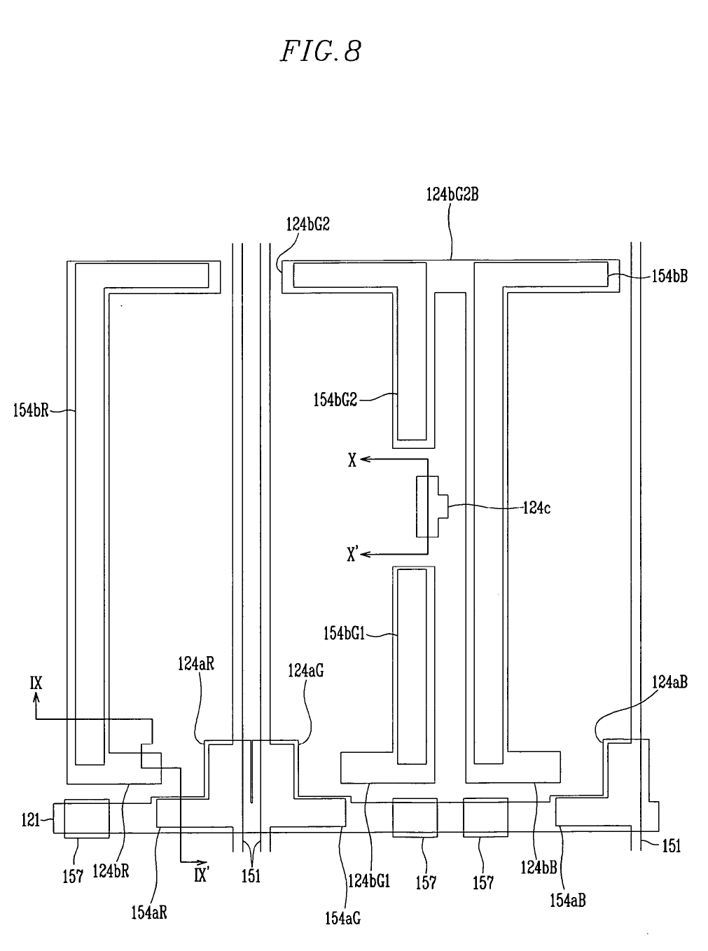

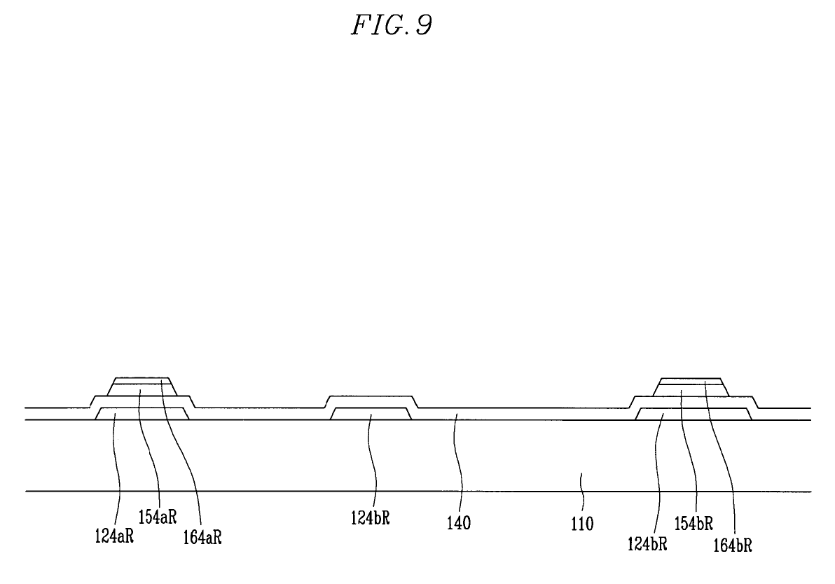

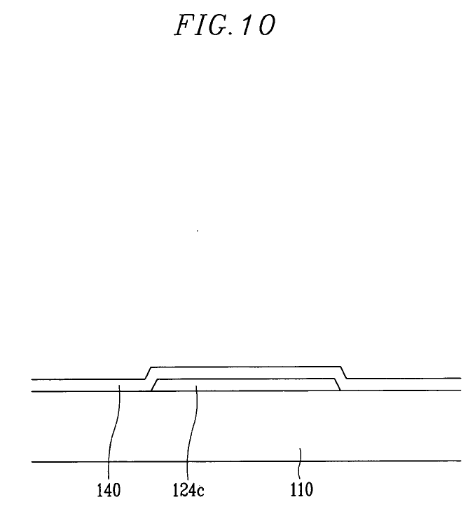

As shown in FIGS. 8, 9 and 10, a gate insulation layer 140, an intrinsic amorphous silicon layer and an extrinsic amorphous silicon layer are formed on the gate metal pattern in succession. Semiconductor patterns 151, 154, 154b and 157 are formed by photolithography. First semiconductor patterns comprise a semiconductor line 151 and a protrusion 154. A second semiconductor pattern comprises 154b.

The second semiconductor pattern 154b of the green pixel comprises a lower second semiconductor pattern 154bG1 and an upper second semiconductor pattern 154bG2. The gate insulation layer 140 may be made of silicon nitride.

A metal layer is deposited on the semiconductor patterns 151, 154, 154b and 157 and on the gate insulation layer 140. The metal layer may be formed of multiple layers. The metal layer comprises one or more of Al, Al alloy, Cr, Mo, and Mo alloy.

A first source electrode 173a, a data line 171, a first drain electrode 175a, a second drain electrode 175b, a second source electrode 173b and a current source line 172 are formed with the metal layer by photolithography. The exposed portion of the extrinsic amorphous silicon 164 is removed so that the intrinsic amorphous silicon is exposed. The exposed intrinsic amorphous silicon may be oxidized by oxygen plasma to stabilize the exposed surface.

In the green pixel, the second source electrode comprises a lower second source electrode 173bG1 [Note: Not shown in the Figs.] and an upper second source electrode 173bG2. The second drain electrode of the green pixel also comprises a lower second drain electrode 175bG1 and an upper second drain electrode 175bG2. The lower second source electrode 173bG1 of the green pixel is coupled to the lower second source electrode 173bB1 of the blue electrode through the lower source electrode connector 173bG1B1. The upper second source electrode 173bG2 of the green pixel is coupled to the upper second source electrode 173bB2 of the blue electrode through the upper source electrode connector 173bG2B2. The upper second drain electrode 175bG2 of the green pixel is coupled to the drain electrode 175bB of the blue pixel through a drain electrode connector 175bG2B.

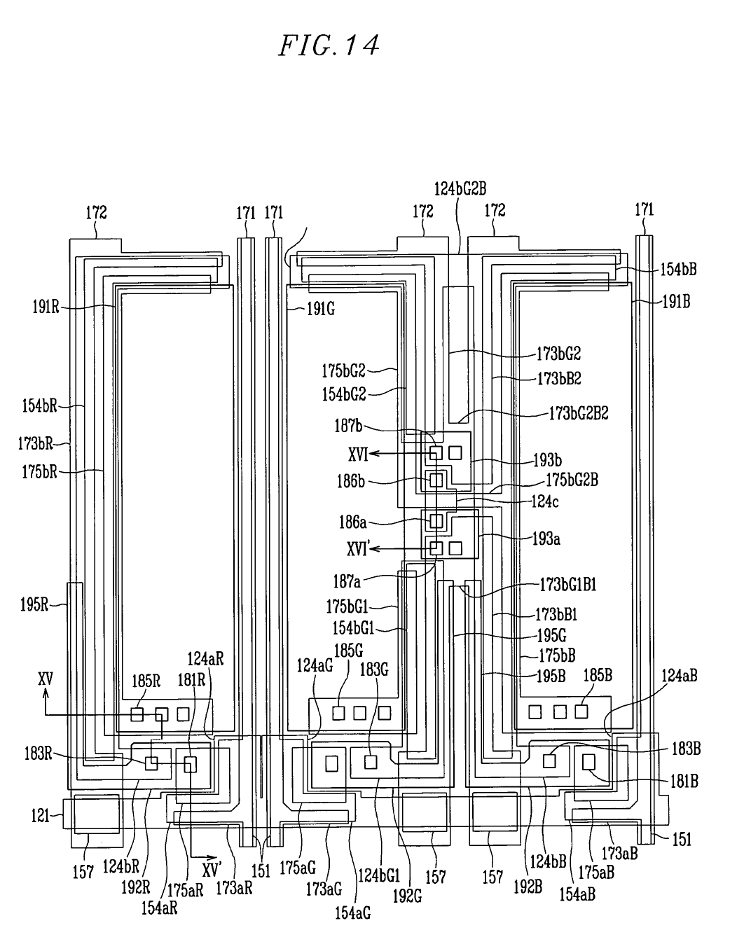

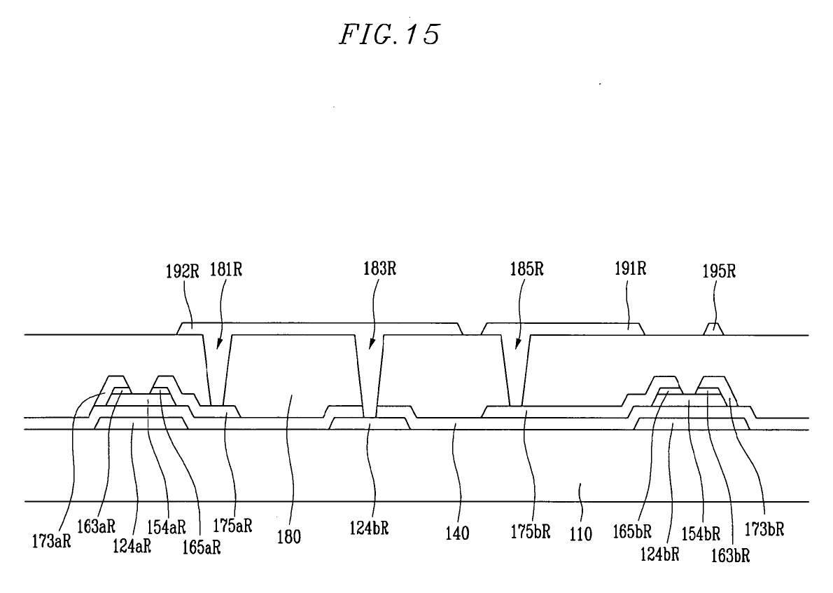

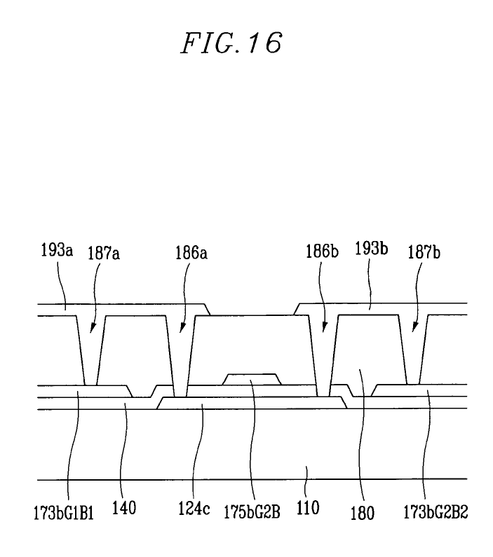

As shown in FIGS. 14, 15 and 16, a passivation layer 180 is formed on the metal pattern, on the TFT channels and on the gate insulation layer 140. The passivation layer 180 is made of an organic insulation material or an inorganic insulation material. Contact holes 181, 183, 185, 186a, 186b, 187a and 187b are formed in the passivation layer 180 and in the gate insulation layer 140 by photolithography. With reference to FIG. 15, the contact hole 181 exposes a portion of the first drain electrode 175a. The contact hole 183 exposes a portion of the second gate electrode 124b. The contact hole 185 exposes a portion of the second drain electrode 175b. With reference to FIG. 16, the contact holes 186a and 186b expose both ends of the first current source line connector 124c.

A pixel electrode 191, connector 192 and second current source line connectors 193a and 193b are formed on the passivation layer 180 by photolithography. The pixel electrode 191 may be made of ITO, IZO, or a low resistivity metal such as Al or Al alloy, for example. A portion of the connector 192 forms a storage capacitance along with the second source electrode 173b.

Referring again to FIG. 3, a wall 803 is formed on the pixel electrode 191 by photolithography. An organic light emitting layer 70 is formed inside the wall 803. A common electrode 270 is formed on the organic light emitting layer 70 and on the wall 803. The common electrode 270 may be made of a low electric resistivity material like Al. The common electrode 270 may be made of IZO or ITO, for example.

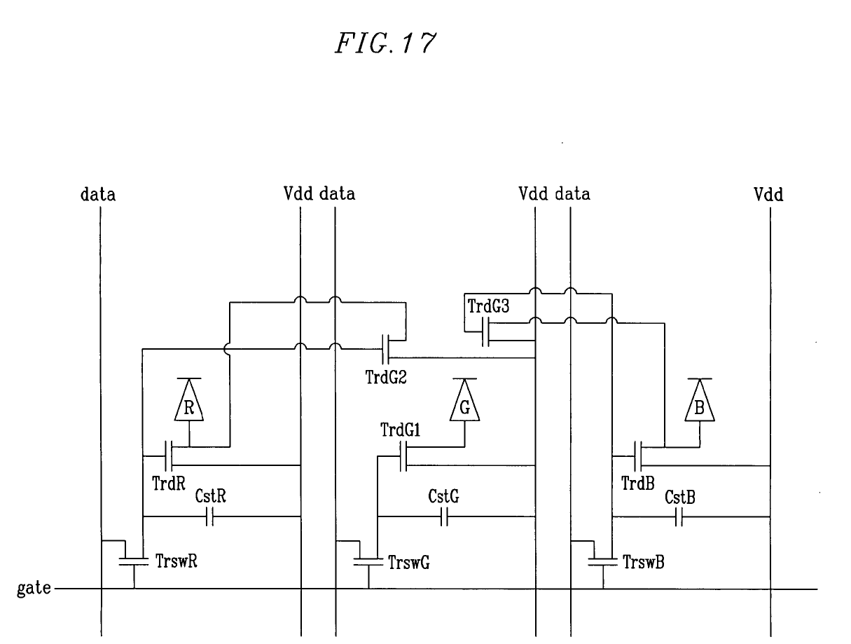

As shown in FIG. 17, three driving transistors may be formed in the green pixel. One driving transistor is coupled to the driving transistor of the red pixel; another driving transistor is coupled to the driving transistor of the blue pixel. Therefore, the two pixels with respective EL layers having the least efficient luminescent efficiencies are supplied with electric current from the pixel having an EL layer with the most luminescent efficiency.

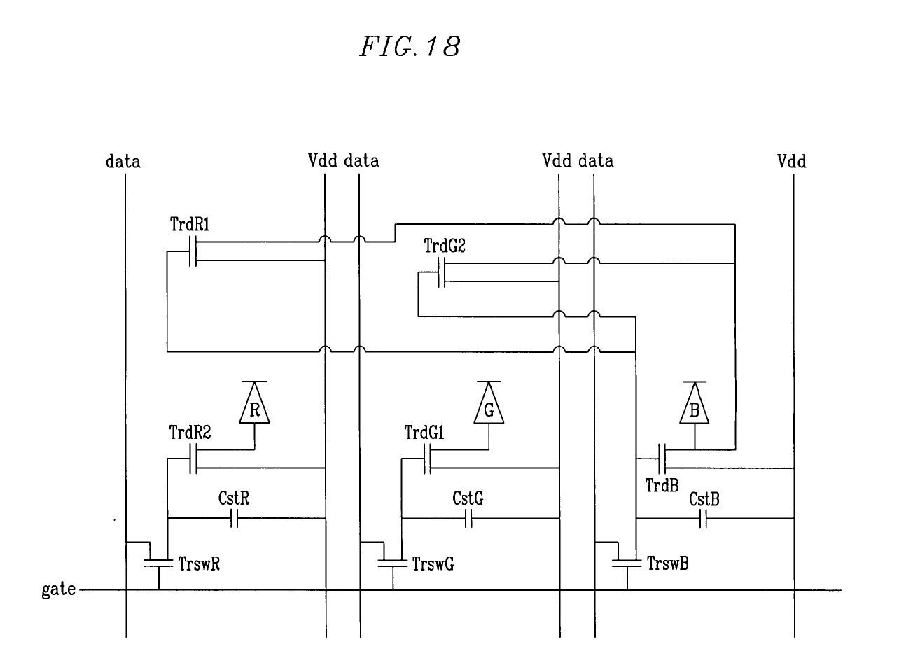

As shown in FIG. 18, another exemplary embodiment of the present invention provides a green pixel having two driving TFTs and a red pixel having two driving TFTs. One driving TFT of the green pixel and one driving TFT of the red pixel are coupled to the driving TFT of the blue pixel, so that current is supplied to the blue pixel from the red pixel and the green pixel.

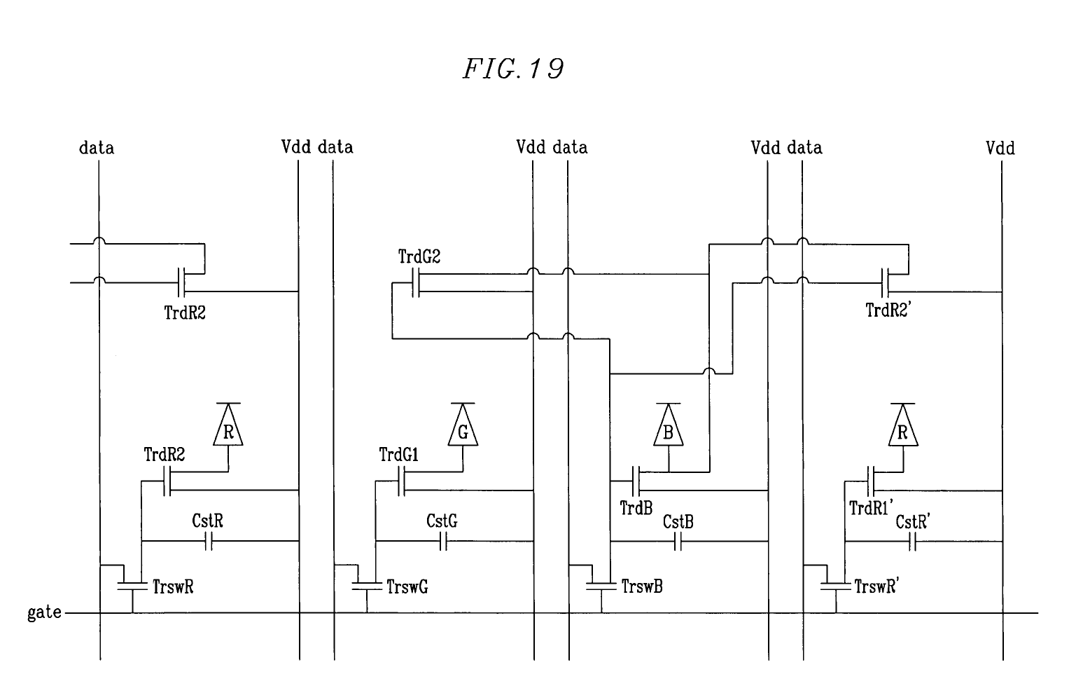

FIG. 19 shows yet another exemplary embodiment of the present invention. Here, a green pixel and a red pixel each have two driving TFTs. One driving TFT of the green pixel and one driving TFT of the red pixel are coupled to the driving TFT of the blue pixel, so that current is supplied to the blue pixel from the red pixel and the green pixel. It will be recognized that the connection line coupling the driving TFT of the blue pixel and the driving TFT of the red pixel in FIG. 18 may be relatively long due the green pixel therebetween. In this case, the driving TFT of the blue pixel is coupled to the driving TFT of an adjacent red pixel (on the right) to shorten the connection line.

Another alternative embodiment may include a driving TFT in the green pixel supplying current to the red pixel. The contents of the exemplary embodiments of the present invention described herein may be applied to other structures of an OLED. For example, an alternative OLED may include four TFTs and one capacitance structure, three TFT and one capacitance structure, or other structure.

It will be apparent to those skilled in the art that various modifications and variations can be made in the present invention without departing from the spirit or scope of the present invention. Thus, it is intended that the present invention cover the modifications and variations of this invention provided they come within the scope of the appended claims and their equivalents.

What is claimed is:

1. A thin film transistor array panel, comprising:
a first switching transistor;
a first driving transistor coupled to the first switching transistor;
a second switching transistor;
a second driving transistor coupled to the second switching transistor; and
a third driving transistor coupled to the second driving transistor.

2. The thin film transistor array panel of claim 1, further comprising:
a first organic electro luminescent matter layer (“first EL layer”);
a second organic electro luminescent matter layer (“second EL layer”);
a first pixel including the first EL layer; and
a second pixel including the second EL layer,
wherein each pixel includes a current source line.

3. The thin film transistor array panel of claim 2, wherein the source electrode of the third driving transistor is coupled to the current source line of the first pixel, the drain electrode of the third driving transistor is coupled to the drain electrode of the second driving transistor, and the gate electrode of the third driving TFT is coupled to the gate electrode of the second driving TFT.

4. The thin film transistor array panel of claim 3, wherein the luminescent efficiency of the first EL layer is better than the luminescent efficiency of the second EL layer.

5. The thin film transistor array panel of claim 4, wherein the first EL layer emits green light and the second EL layer emits red light or blue light.

6. The thin film transistor array panel of claim 3, further comprising:
a third switching TFT;
a forth driving TFT coupled to the third switching TFT;
a third organic EL layer; and
a third pixel having a current source line.

7. The thin film transistor array panel of claim 6, further comprising:
a fifth driving TFT,
wherein the source electrode of the fifth driving TFT is coupled to the current source line of the first pixel, the drain electrode of the fifth driving TFT is coupled to the drain electrode of the forth driving TFT, and the gate electrode of the fifth driving TFT is coupled to the gate electrode of the forth driving TFT.

8. The thin film transistor array panel of claim 7, wherein the luminescent efficiency of the first EL layer is better than the luminescent efficiency of the second EL layer and the third EL layer.

9. The thin film transistor array panel of claim 8, wherein the first EL layer emits green light, the second EL layer emits red light, and the third EL layer emits blue light.

10. The thin film transistor array panel of claim 6, further comprising:
a fifth driving TFT,
wherein the source electrode of the fifth driving TFT is coupled to the current source line of the third pixel, the drain electrode of the fifth driving TFT is coupled to the drain electrode of the second driving TFT, and the gate electrode of the fifth driving TFT is coupled to the gate electrode of the second driving TFT.

11. The thin film transistor array panel of claim 10, wherein the luminescent efficiency of the second EL layer is worse than the efficiency of the first EL layer and the third EL layer.

12. The thin film transistor array panel of claim 11, wherein the first EL layer emits green light, the second EL layer emits blue light and the third EL layer emits red light.

13. The thin film transistor array panel of claim 2, further comprising:
a common electrode on the first EL layer;
a pixel electrode formed in the first pixel area; and
a wall confining the EL matter,
wherein the wall is formed between the pixel electrode and the common electrode.

14. The thin film transistor array panel of claim 13, wherein the wall is made of an insulation material, the pixel electrode is made of an opaque metal and the common electrode is made of a transparent conductor.

15. The thin film transistor array panel of claim 13, wherein the wall is made of an insulation material, the pixel electrode is made of a transparent conductor and the common electrode is made of an opaque metal.
